(19) United States
(12) Patent Application Publication
(10) Pub. No.: US 2007/0194378 A1
(43) Pub. Date: Aug. 23, 2007

(54) Eeprom memory cell for high temperatures

(75) Inventors: Steffen Richter, Apfelstaedt (DE); Sonja Richter, Ilmenau (DE); Dirk Nuernbergk, Erfurt (DE); Dagmar Kirsten, Ilmenau (DE)

Correspondence Address: STEVENS & SHOWALTER LLP, 7019 CORPORATE WAY, DAYTON, OH, 45459-4238, US

(73) Assignee: X-FAB Semi Conductior Foundries AG, Erfurt (DE)

(21) Appl. No.: 10/592,246

(22) PCT Filed: Mar. 10, 2005
(86) PCT No.: PCT/EP05/51099

§ 371 Date: Sep. 8, 2006

(30) Foreign Application Priority Data
Mar. 11, 2004 (DE) 10 2004 011 858.2

(51) Int. Cl. H01L 27/12

(52) U.S. Cl. 257/347

(57) ABSTRACT

An electrically erasable programmable read-only memory (EEPROM) memory cell is produced using a silicon on insulator (SOI) technology, which is suitable for use at high temperatures. An EEPROM cell is formed from a memory transistor comprising a floating gate and a high-voltage select transistor. The select transistor comprises a freely allocatable body connection for an inner active region and an additional drift region in the source region.

The invention relates to an EEPROM memory cell (electrically erasable programmable read-only memory) for high temperatures which is produced with MOS transistors on the basis of the SOI technology (silicon on insulator).

There are certain advantages for transistors that are produced on an SOI substrate as compared with transistors that are produced on a semiconductor solid substrate, e.g. the avoiding of a parasitic thyristor structure, smaller parasitic capacities, an increased immunity to highly energetic radiation and the like, which make SOI technology an attractive alternative to components on semiconductor solid substrates. However, there are certain SOI-specific limitations upon the operation of SOI-MOS transistors due to the complete insulation with respect to adjacent components, which is desired per se.

With respect to FIG. 1 a typical SOI structure is described which shows two n-channel transistors which are designed for different voltages. An SOI structure 100 is represented in FIG. 1, which comprises a silicon substrate 101 on which an insulating layer 102 that is also designated as a buried oxide layer is formed. Two transistor structures 110 and 120 are formed on the oxide layer, the transistor structure 110 having a strongly n-doped drain region 111 and a strongly n-doped source region 112, which are separated by a slightly p-doped inner active region 113 which is also designated as a body and in which a conductive n-channel is also formed upon the operation of the transistor 110. A gate 114 is disposed above the inner active region 113 which is electrically insulated from the inner active region 113 and from the drain and source regions 111, 112 by an insulating layer 115 which is also designated as a gate oxide. Moreover, the transistor 110 comprises a contact region 116 which is in connection with the inner active region 113 which is also designated as a body. The shown transistor structure 110 has a substantially symmetrical structure with respect to the drain region 111 and the source region 112.

The transistor structure 120 comprises a strongly n-doped drain region 121 and a strongly n-doped source region 122, a less doped extension and/or drift region 127 being provided in the drain region 121. With its drift region 127 the drain region 121 adjoins an inner active region 123 so that there is a lesser concentration gradient of the doping substance in the case of the resulting PN transition 128 between the regions 123 and 127 than is the case with the corresponding PN transition 129 of the source region 122 with the inner active region 123. Moreover, the transistor 120 comprises a contact region 126 which is connected with the inner active region 123 and the source region 122. A gate 124 which is disposed above the inner active region 123 is insulated from the inner active region 123, the drift region 127 and the source region 122 by an insulating layer 125.

In the case of a typical operating situation of the structure 100 the drain region of the transistor 110 can be acted upon with a positive supply voltage, e.g. 5 volts, whereas the source region 112 is at zero potential. A conductive channel is built up in the inner region 113 near the boundary layer to the insulating layer 115 by applying a suitable control voltage to the gate electrode 119. Here, the conductivity of the channel depends on the control voltage and on a characteristic quantity determined by the transistor structure, which is designated as threshold voltage or starting voltage. I.e. as soon as the control voltage at the gate electrode 114 exceeds the starting voltage, a conductive channel is Is built up in the inner active region 113 and makes a current flow between the drain region 111 and the source region 112 possible. Upon the applying of the control voltage to the gate electrode 114, e.g. by applying a rising edge from 0 volt to 5 volts, a high electrical field results in particular at the drain side, i.e. at the parasitic capacity, which is formed by the gate electrode 114 and the drain region 111 with the intermediate gate oxide layer 115 as a dielectric, which, in the case of high drain voltages, results in that the electrodes can receive a sufficiently high kinetic energy so that a penetration into or even a penetration through the gate oxide layer 115 is possible. This effect which is undesired per se in a normal transistor, i.e. the capturing of highly energetic electrodes in the gate oxide layer 115 and/or the penetration through the gate oxide layer 115 is advantageously utilized in an EEPROM memory cell, since the starting voltage of the transistor can be shifted by means of the captured charge carriers as will still be explained in greater detail in the following.

Substantially the same behavior results for the transistor 120, a different field distribution with lower peak values results at the drain side due to the drift region 127 with the lower concentration of doping substance, the drain voltage being the same. I.e. with a suitable design of the drift region 127 high drain voltages can be switched with the transistor 120 as compared with the symmetrical structure of the transistor 110.

The inner active region, e.g. the regions 113 and 123, is not automatically contacted in the transistors in SOI technology. As is shown in FIG. 1, there is, however, the possibility to connect these regions by means of corresponding contact regions 116, 126 or to have them freely floating. MOS transistors with freely floating body potential are called a floating body (FB components), whereas transistors whose contact regions 116, 126 are wired, i.e. are acted upon by a reference potential, are typically designated as body-tied (BT) transistors. Here, the contact region 116 and/or 126 is typically connected with the respective source regions. If the respective contact regions 116, 126 remain unwired, a generation of avalanches, i.e. a generation of pairs of electron holes, occur at the drain side, in addition to the aforementioned capturing of highly energetic electrons in the respective gate oxide layer, in the case of high drain voltages. The electrons caused by the generated pairs of electron holes also flow off via the drain together with the channel charge carrier—the electrons in the example of the shown n-channel transistors. The other kind of charge carriers—i.e. the holes in the shown n-channel transistors—remain in the inner active region 113 and/or 123 so that a charging results there. This may result in a change in the starting voltage since then a conductive n-channel is consequently already formed in the case of a lower gate voltage so that in the case of the same gate voltage a higher output voltage flows (kink effect). This effect is undesired in most circuits, consequently body-tied transistors are primarily used.

FIG. 2 schematically shows the circuit diagram of an EEPROM memory cell 200 for applications with temperatures up to about 150° C. The memory cell 200 is made up of two n-channel MOS transistors that have a similar structure as the transistors 110 and 120 that are shown in FIG. 1. Here, the transistor 110 represents a memory transistor, the structure of the transistor 110 being modified as compared with FIG. 1, so that a further conductive layer 118 is provided, which is electrically insulated from the gate electrode 114 and the inner active region 113. The electrically conductive layer 118 is also called a floating gate. Moreover, there is a small region (not shown) with a thin oxide between the drain 111 of the memory transistor 110 (translator's note: here something is missing), through which a tunnel current flow can start between the drain 111 of the memory transistor 110, if a sufficiently high drain voltage results in a corresponding acceleration of the channel charge carriers and thus to a correspondingly high probability of a penetration through the thin oxide surface, as this was explained above. The region with the thin oxide is also called injector window, the appurtenant part of the drain region 111 being accordingly designated as an injector. The information of the memory cell 200 is stored in the form of a shifting of the starting voltage, i.e. a corresponding applied control voltage which is applied to the gate 114 (positive voltage) is shielded by means of introducing channel charge carriers into the floating gate 118 so that a higher voltage is required for building up a conductive channel. Conversely, the formation of a conductive channel can already be brought about upon the introducing of positive charge carriers into the floating gate 118 without an additional control voltage at the gate electrode 114 being required. In general, the mechanism for introducing charges into the floating gate 118 through an insulating layer without an electrical breakdown taking place is called Fowler Nordheim tunneling, the Fowler-Nordheim theory quantitatively describing the quantum-mechanical effect of the penetration through a potential barrier by the charge carriers.

In order to be able to implement the various operating conditions of the memory cell 200, i.e. the programming, the erasing, the reading out, in a controlled fashion for a plurality of memory cells that are connected with each other, the select transistor 120 is required which has substantially the same structure as the transistor 120 of FIG. 1. Moreover, the select transistor 120 is connected to the drain region 111 of the memory transistor 110 with its source region 122 in order to form a node 201 therewith. During programming, a suitably high voltage which is sufficient for the triggering of tunnel currents is applied to the gate 124 of the select transistor 120 which is also called a select gate (SG) and to the drain 121 (D). Here, the gate 114 of the memory transistor 110, which is also called a control gate (CG) remains at 0 volts. The source region 112 of the memory transistor 110 (S) remains unwired. Due to the high drain voltage which is also present at the node 201 and thus to the drain 111 via the selection transistor 120 which is switched through, a high electrical field results with respect to the control gate 114 which is at 0 volts so that electrons flow off from the floating gate 118 due to the tunnel effect so that the floating gate is positively charged. This positive charge is also maintained after the switching off of the programming voltage and brings about a corresponding shifting of the starting voltage to small or negative values, as this was already explained above.

Upon the erasing of the cell 200 0 volt are in each case applied to the drain region 121 (D) of the select transistor 120 and to the source region 112 (S) of the memory transistor 110, whereas the select gate 124 (SG) and the control gate 114 (CG) are acted upon by the high programming voltage. A correspondingly high electrical field results from this, which is directed from the floating gate 118 to the injector and results in the starting of a corresponding tunnel current so that electrons get onto the floating gate 118. I.e. the floating gate 118 is negatively charged even after the switching off of the programming voltage at the gate 114 so that the starting voltage is shifted to high values since now a higher gate voltage is required at the control gate 114 in order to form a conductive channel in the inner active region 113 of the memory transistor 110.

Upon the reading out of the memory cell 200, a constant voltage, e.g. 0 Volts, is applied to the control gate 114 (CG), whereas a voltage of e.g. 5 volts is applied to the select gate 124 (SG) and the drain 121 (D) of the select transistor 120, whereas the source 121 of the memory transistor 110 is at 0 volt. The conditions “erased” and “written” can now be differentiated by means of the starting current flow, since, for a given voltage at the control gate 114 (CG), e.g. 0 volts, substantially no current flow takes place in the erased condition, whereas a current flow through the memory transistor 110 takes place in the programmed condition.

If the EEPROM cell 200 is operating at high temperatures, i.e. at temperatures of about 150° C., a high thermal generation rate of pairs of electron holes results in particular in the drift region 127 which results in an increased leakage current to the source 122 of the select transistor 120 and thus to the inner node 201 so that it is charged up to the voltage present at the drain 121. During programming of a memory cell that is coupled with the cell 200, during which the control gate 114 (CG) of the memory transistor 110 together with the other memory cell to be programmed is at 0 volt, a relatively high voltage occurs between the gate 114 and the node 201 despite a voltage of 0 volt at the select gate 124 (SG) of the select transistor 120 due to the charged node 201, so that an unintended programming of the cell 200 can take place which, thus, can result in a data corruption. I.e. the conventional high-voltage transistor 120 does no longer comply with its function as a select transistor.

Consequently, memory cells are used in EEPROM memories available on the marked, which are suited for applications at higher temperatures, which have an additional transistor which connects the inner node 201 of a not selected memory cell during critical procedures with ground potential in order to thus prevent a charging of the inner node 201 and thus a corresponding unintended data corruption.

The providing of a third transistor in the memory cell requires, however, a high requirement of valuable chip surface so that a cost-efficient and/or space-saving integration of an EEPROM memory is not possible in many high-temperature applications.

The invention is based on the object of providing a technology which makes a more space-efficient structure of an EEPROM memory cell for high-temperature applications possible.

According to an aspect of the present invention this object is attained by an electrically erasable, programmable read-only memory cell (EEPROM memory cell) in SOI technology which is also suitable for high temperatures, the memory cell comprising an MOS memory transistor with a floating gate. Moreover, the memory cell comprises an MOS select transistor which is designed as a high-voltage transistor and which comprises a polysilicon gate electrode, a drain region with a connection and a source region, an inner active region disposed below the gate electrode and having a contact, a drift region being additionally provided in the source region so that diodes are present at the PN transitions between the drain region and the inner active region and between the source region and the inner active region. The diodes originate from the separately contacted body, not from the drift region.

An arrangement results in particular due to the structure of the select transistor according to the invention, in which a thermally generated leakage current is now also generated on the source side of the select transistor so that the leakage current that conventionally is directed towards the source and thus charging the inner node (cf. FIG. 2, node 201) can be compensated to a high degree by the leakage current generated in the source region, a very high degree of compensation being achievable at high temperatures, i.e. in a range of about 100 to 200° C., since, here, the thermal portions of the leakage currents dominate.

In a further advantageous embodiment the electrically erasable, programmable read-only memory cell does not comprise more than two MOS transistors. Due to this structure, the memory cell can be built up in an extremely space-efficient fashion.

In a further advantageous embodiment the contact is designed in such a way that it can be freely acted upon by a potential. Thus, the contact that is connected with the inner active region of the select transistor can thus be connected, if required, with a suitable reference potential, e.g. the ground potential, in order to avoid and/or reduce any charging of the inner active region of the select transistor so that effects on the starting voltage of the select transistor, which result from any charging of the inner active region, can be avoided or at least reduced.

In a further embodiment the select transistor has a drift region in its drain region. I.e., as in conventional EEPROM memory cells, the select transistor has a high electric strength so that a reliable operation is ensured.

In a further advantageous embodiment, the drain region and the source region of the select transistor are designed substantially symmetrically to each other. Due to this structure, a high degree of symmetry results even in the case of the leakage currents occurring at high temperatures so that a high degree of compensation and thus a minimization of the charging of the inner node can be achieved.

According to a further aspect of the present invention the aforementioned object is attained by an electrically erasable, programmable read-only memory cell (EEPROM memory cell) in SOI technology, the memory cell comprising an MOS memory transistor with floating gate and a select transistor. The select transistor comprises a drain region with a connection and a source region and an inner region that is disposed between the drain region and the source region and connected with a freely allocatable connection.

Due to this design of the select transistor of the EEPROM memory cell according to the invention, a thermally caused leakage current which starts from the drain to the inner active region and from the source to the inner active region can be reliably carried off, since the freely allocatable connection enables the connection of the inner active region with an optional reference potential, e.g. ground potential.

In a further embodiment a drift region is in each case provided in the drain region and the source region. The required high-voltage stability of the select transistor can be achieved with this arrangement.

Advantageously, the drain region and the source region are built up substantially symmetrically to each other. A high degree of symmetry in the transistor behavior can be achieved with this structure, in particular in view of the thermally generated leakage currents at high temperatures so that the data integrity of the EEPROM memory cell is reliably ensured in particular at very high temperatures.

In an advantageous embodiment the EEPROM memory cell does not comprise more than two transistor structures, whereby an extremely compact and space-efficient memory cell structure results.

According to a further aspect of the present invention, the aforementioned object is solved by a process for operating an electrically erasable, programmable read-only memory cell (EEPROM memory cell). The process comprises the provision of a memory transistor with floating gate that is produced in SOI technology and of a select transistor and the connecting of an inner active region of the select transistor, which can be freely acted upon by a potential, with a specific reference potential during at least one specified functional status of the memory cell in order to carry off thermally generated leakage currents in the select transistor. As already stated above, the data integrity of the EEPROM memory cell can be obtained with this process also at very high temperatures, since a charging by thermally caused leakage currents can be at least reduced, whereby a detrimental effect of a possible charging of the inner active region of the select transistor can be efficiently avoided at least temporarily by the carrying off of corresponding leakage currents.

In a further embodiment the at least one specified functional status of a read status. Due to the connecting of the inner active region with the specified reference potential during the read status it can be achieved that the select transistor has an inner active region being at reference potential at least after each programming or erasing process so that detrimental effects on the starting voltage of the select transistor are substantially avoided.

According to a further aspect of the present invention the object is attained by a process for producing an electrically erasable, programmable read-only memory cell. The process comprises the formation of a memory transistor with floating gate on an SOI substrate, the formation of a select transistor on the SOI substrate and the formation of a contact region which is insulated from a drain region and a source region of the select transistor and connected with an inner active region of the select transistor.

In a further embodiment the formation of the select transistor comprises: formation of the drain region with a drift region and formation of the source region with a drift region.

In a further embodiment the process also comprises the formation of a connection that can be connected with a potential source external to the memory cell and is electrically connected with the contact region.

Further embodiments, advantages and features of the invention are revealed by the subsequent description of examples which, with the inclusion of the drawings, enable a more extensive understanding of the claimed invention.

In the drawings:

FIG. 1 shows a perspective view of an SOI structure with two n-channel MOS transistors;

FIG. 2 schematically shows, as a circuit diagram, the structure of a known EEPROM memory cell with transistor structures that are similar to those of FIG. 1;

FIG. 3 schematically shows a circuit diagram of a transistor structure for an EEPROM memory cell for high temperatures according to a first embodiment of the invention;

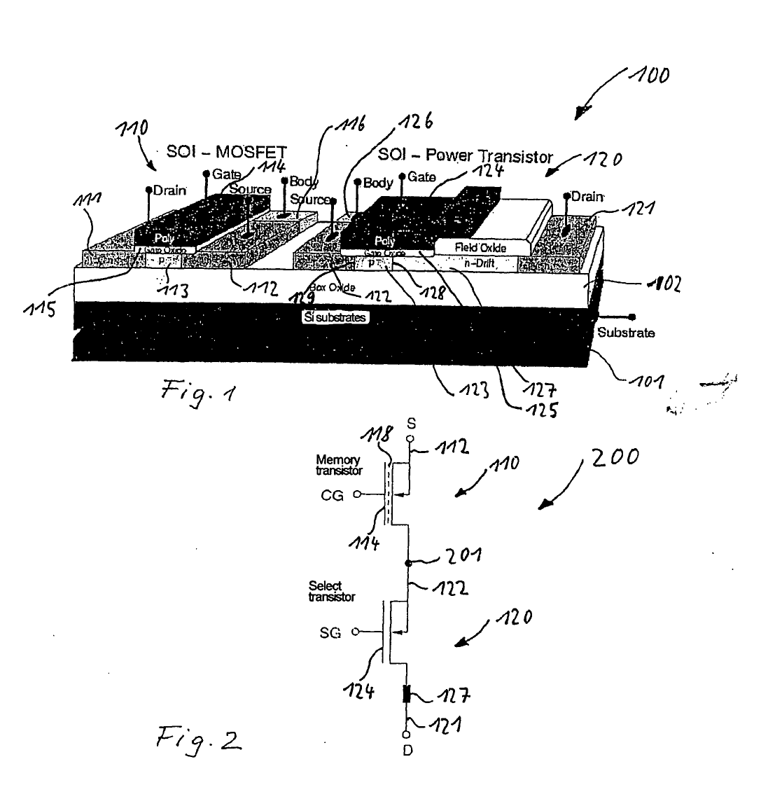

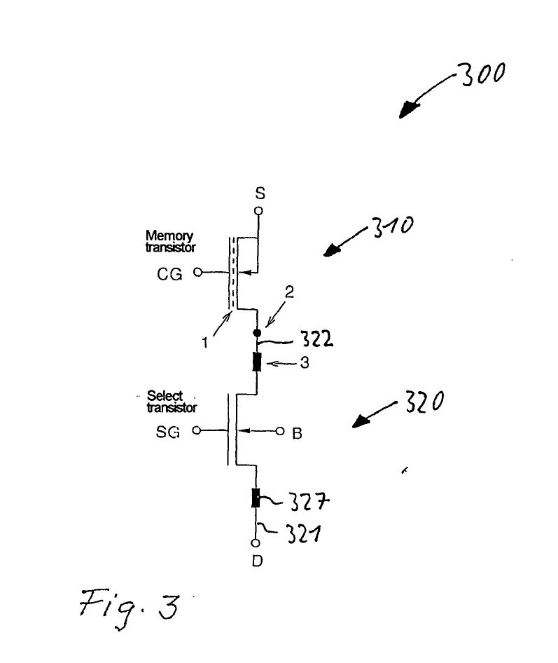

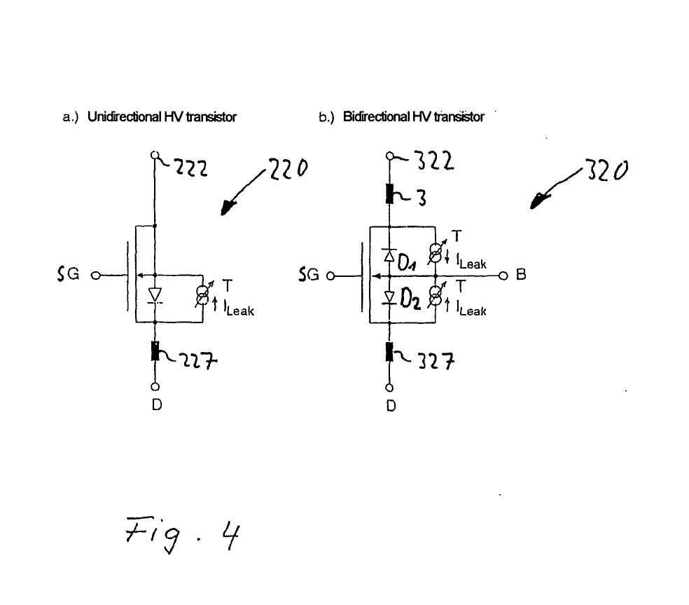

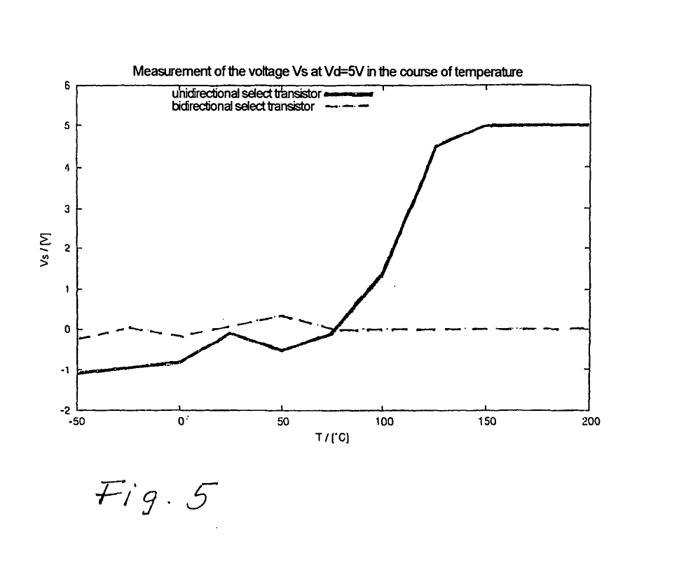

FIG. 4 shows a comparison of a conventional unidirectional high-voltage select transistor, in which the inner active region and the source region are connected and a bidirectional high-voltage select transistor in which a contact for the inner active region is separately led out, according to a first embodiment of the invention;

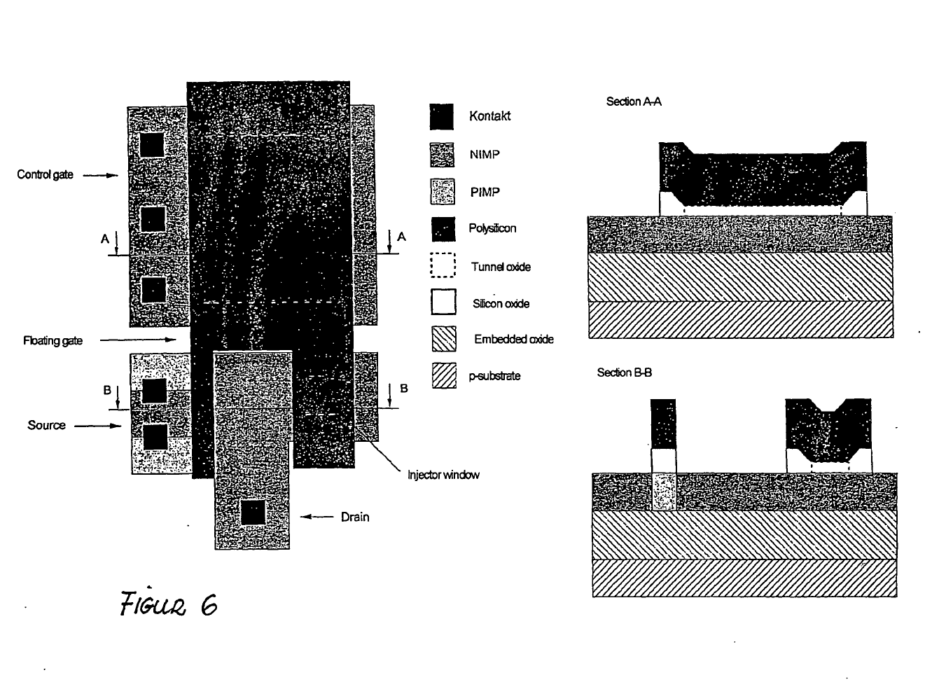

FIG. 5 shows the march of temperature of the voltage at the source of a conventional select transistor as compared with a new select transistor across a temperature range of −50° C. to 200° C.;

FIG. 6 shows a top view and two sectional views of a typical SOI memory transistor as it can be used in the memory cell according to the invention;

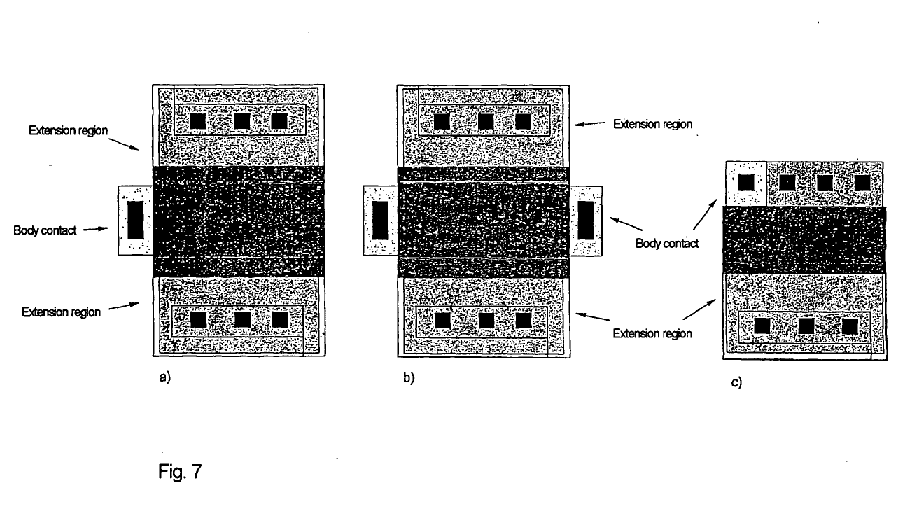

FIG. 7a,

FIG. 7b a top view of select transistors according to illustrative embodiments of the invention, the inner active region being separately contacted and a drift region being provided at the source side;

FIG. 7c a top view of a typical conventional select transistor;

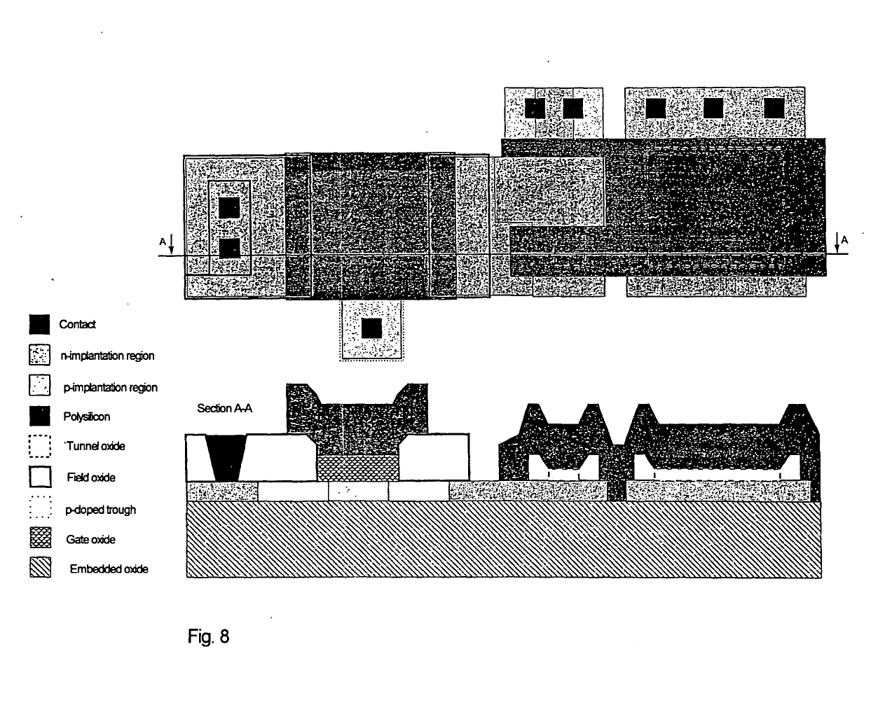

FIG. 8 a top view and a sectional view of a memory cell having a memory transistor and a select transistor according to a illustrative embodiment of the present invention.

In general, an EEPROM memory cell structure is to be described in which a memory transistor with floating gate and a select transistor with a freely allocatable connection for an inner active region and with an additional drift region in the source region of the select transistor are provided.

FIG. 3 schematically shows a circuit diagram of a transistor structure for an EEPROM memory cell 300 according to an illustrative embodiment of the present invention. The memory cell 300 comprises a memory transistor 310 and a select transistor 320. In an especially advantageous embodiment no further transistor structures are provided in the memory cell 300. The memory transistor 310 comprises a source S, a control gate CG, a floating gate 1 and a drain region, which is connected with the inner node 2. The structure of the memory transistor 310 is similar to the memory transistor 210 as it is described with reference to FIG. 2 and FIG. 1 so that a more detailed description is omitted. A typical structure of the memory transistor 310 is also shown in FIG. 6 by way of example, in which the top view and two sectional views are shown.

The select transistor 320 comprises a select gate SG, a drain region D (with 321) with a drift region 327, a source region 322 with a drift region 3, the source region 322 being internally connected with the inner node 2. Moreover, the transistor 320 comprises an inner active region 123 (see FIG. 1) which can be freely acted upon with an optional potential by means of a connection B. Further structural features of the select transistor 320 are similar to those of the select transistor 220 and/or the transistor 120 as they were previously described with reference to FIGS. 1 and 2. A top view of an exemplary embodiment of the select transistor 320 is shown in FIG. 7a, the connection B designated as a body contact being provided at one side in the width direction of the transistor, whereas two contacts are shown in FIG. 7b. As compared with this, a typical conventional select transistor with a body contact at the source side and without extension region at the source side is shown in FIG. 7c.

During operation of the memory cell 300, i.e. upon the setting of one of the operating conditions programming, erasing, reading out, the same operations can substantially be implemented as this was described above with reference to the memory cell 200 of FIG. 2. I.e. upon the writing and/or programming of the memory cell 300 a correspondingly high programming voltage can be applied both to the drain D and to the select gate SG, the voltage 0 being present at the control gate CG so that then a corresponding charge transfer to the floating gate 1 can take place. Conversely, the voltage 0 is applied to the drain D and the source S upon the erasing of the memory cell 300, whereas the high programming voltage acts upon the select gate SG and the control gate CG so that a reverse charge transport can take place. Moreover, an impairment of the select gate SG due to the capturing of high-energy charge carriers is low in this operating condition, as well, i.e. a high voltage at the select gate SG and zero volt at the sources due to the additional drift region 3 in the source region S for generating a moderate doping substance gradient, as this was also described at the drain side for the conventional select transistor 120.

As already mentioned above, a charging of the inner node 2 is low in particular during programming of one or several adjacent cells of the memory cell 300, in which, thus, the select gate SG of the select transistor 320 is at 0 volt, so that an undesired programming of the floating gate 1 can be reliably avoided up to temperatures of 200° C. or, in some embodiments, even higher.

During the reading of the memory cell 300, the control gate CG being e.g. at 0 volt and the drain D and the select gate SG are at 5 volts, the connection B and thus the inner active region of the select transistor 320 may also be connected to a suitable reference potential, e.g. 0 volt, so that a charging of the inner active region that is caused by thermal leakage currents is avoided and thus a stable functioning of the select transistor 320 is also ensured during the reading operation. Thus, this means that the EEPROM memory cell 300 according to the invention can be triggered in the same fashion for the individual functional states as the conventional high-temperature memory cell with three transistors.

FIG. 4 shows a comparison of a conventional high-voltage select transistor which is represented by the select transistor 220 (cf. FIG. 2) and a bidirectional high-voltage select transistor according to the invention, which is represented by the transistor 320 (cf. FIG. 3). In the conventional select transistor 220, the source region 222 is connected with the inner active region (body) of the transistor so that only a PN transition is active as a diode as this is represented in the Fig. Upon the occurrence of higher temperatures a leakage current I_{LEAK} is generated which is represented in the Fig. as a variable current source. As already explained above, pairs of electron holes are generated by the thermal energy, the electrons (for an N-channel transistor) being able to flow off via the drain D, whereas the holes migrate to the inner active region as this is represented by the direction of the arrow of the variable current source so that a corresponding charging also occurs at the source 222, since the inner active region and the source region 222 are connected with each other.

As opposed to this, the inner active region is not connected with the source region 322 in the transistor 320 according to the invention, but can be acted upon with a reference potential via a separate, freely allocatable connection B, if required. Accordingly, a PN-transition occurring from the inner active region to the source region 322 is also effective, which is represented by the diodes D1 and D2 in the drawing. Due to the structure of the transistor 320 with the additional drift region 3 in the source region 322, corresponding leakage currents are also caused there at higher temperatures as this is represented by the additional variable current source in the Fig. If the electrons flow off from the source region 322 in the case of a drain current, a leakage flow to the inner active region begins so that a charging of the source region 322 and thus of the inner node 2 (cf. FIG. 3) can be substantially avoided. Depending on the size of the respective thermally indicated (translator's note: should read “induced”) leakage currents, a charging of the inner active region results, it being, however, possible that these leakage currents can be carried off, if required, due to the freely allocatable wiring of the inner active region by means of the connection B. Due to this, a negative influencing of the starting voltage of the transistor 320 can be prevented due to a charging of the inner region 320 (translator's note: the reference numeral is incorrect).

FIG. 5 shows qualitatively the behavior of the transistors 220 and 320 of FIG. 4, if they are operated across a wide temperature range of −50 to +200° C. In FIG. 5, the solid line shows the voltage of the transistor 220 at its source 222, if the drain voltage is 5 volts and the voltage at the select gate SG is 0 volt. It can be clearly recognized that, at temperatures as of 100° C., a high increase of the voltage at the source 222 can be recognized so that thus the corresponding node (cf. node 201 in FIG. 2) is charged and thus may result in an undesired programming of the memory transistor. As opposed to this, the broken curve shows the corresponding behavior of the transistor 320 according to the invention, it being possible to prevent an increase in voltage at the source 322 and thus also at the inner node 2 (cf. FIG. 3) in particular at higher temperatures, i.e. at 100° C. and higher, so that the data integrity of the memory cell 300 and of an EEPROM memory which comprises many memory cells 300 that are wired with each other is maintained even at high temperatures.

The inventive EEPROM memory cell structure as it is e.g. schematically represented in FIG. 3 can be built up using conventional production processes, the corresponding process steps and lithography masks as they are used for the formation of the drain . region including the corresponding drift region may also be used for the formation of the source region if a symmetrical structure of the transistor cell is desired. Moreover, a corresponding change of the lithography mask and of the process steps is required during the step of the formation of the contact region of the select transistor to the effect that the inner active region of the select transistor is contacted without establishing an electrical connection to the drain region and the source region and that a corresponding connection for the inner active region is provided.

FIG. 8 schematically shows a corresponding top view and a sectional view of a memory cell according to an illustrative embodiment in order to illustrate how the layout design can be implemented during production.

Thus, the present invention provides an efficient technology in order to provide an EEPROM cell for the use in a wide temperature range, the EEPROM cell comprising a memory transistor with MOS technology with a floating gate and a high-voltage transistor with MOS technology as the select transistor, which are both produced on an SOI substrate. The select transistor comprises a freely allocatable body connection and has an additional drift zone in its source region. Thus, according to the invention a third transistor for applications in which temperatures in the range of −50 to +200° C. or more occur can be renounced due to constructional changes in the structure of the high-voltage transistor, due to which valuable chip surface and thus costs can be saved.

1. An electrically erasable, programmable read-only memory cell in a silicon on insulator (SOD technology, the memory cell being suited for a temperature of more than substantially 100° C., comprising:
a MOS memory transistor with a floating gate and a MOS select transistor which is designed as a high-voltage transistor, wherein the select transistor comprises:
a polysilicon gate;
a drain region with a connection and a source region;
an inner active region with a contact, which is disposed below the gate, a first drift region being additionally provided in the source region,
so that diodes are present at PN transitions between the drain region and the inner active region and between the source region and the inner active region.

2. The electrically erasable, programmable read-only memory cell according to claim 1, wherein the memory cell does not comprise more than two MOS transistors.

3. The electrically erasable, programmable read-only memory cell according to claim 1, wherein the contact is designed in such a way that it can be freely acted upon with a potential.

4. The electrically erasable, programmable read-only memory cell according to claim 1, wherein the drain region of the select transistor comprises a second drift region.

5. The electrically erasable, programmable read-only memory cell according to claim 1, wherein the drain region and the source region are substantially symmetrically designed with respect to each other.

6. A programmable read-only memory cell in an SOI technology which is suitable to be electrically erased, comprising:
a MOS memory transistor with a floating gate;
a select transistor having a drain region with a first connection, a source region and an inner active region, which is disposed between the drain region and the source region and connected with a freely allocatable second connection.

7. The electrically erasable, programmable read-only memory cell according to claim 6, wherein a drift region provided in the drain region and the source region.

8. The electrically erasable, programmable read-only memory cell according to claim 6, wherein the drain region and the source region are built up substantially symmetrically to each other.

9. The electrically erasable, programmable read-only memory cell according to claim 6, wherein the memory cell does not comprise more than two transistor structures.

10. A process for operating an electrically erasable, programmable read-only memory cell, the process comprising:
providing a memory transistor produced in an SOI technology with floating gate and a select transistor;
connecting an inner active region of the select transistor, which can be freely acted upon with a potential, with a specified reference potential during at least one specified functional status of the memory cell for carrying off thermally generated leakage currents in the select transistor.

11. The process according to claim 10, wherein the at least one specified functional status comprises a read status.

12. A process for producing a programmable read-only memory cell for an electric erasing process, the process comprising:
forming a memory transistor with a floating gate on an Sol substrate;
forming a select transistor on the SOI substrate;
forming a contact which insulates from the drain region and the source region of the select transistor and is connected with an inner active region of the select transistor.

13. The process according to claim 12, wherein the formation of the select transistor comprises forming the drain region with a first drift region and forming the source region with a second drift region.

14. The process according to claim 12, further comprising: forming a connection which can be connected with a potential source external to the memory cell and is electrically connected with the contact.
